(19) United States
(12) Patent Application Publication
(10) Pub. No.: US 2025/0351505 A1
(43) Pub. Date: Nov. 13, 2025

(54) SIN CAPPING ON METAL GATE

(71) Applicant: Taiwan Semiconductor Manufacturing Company, Ltd., Hsinchu (TW)

(72) Inventors: Pei-Yu Chou, Hsinchu City (TW); Meng-Ku Chen, Taipei City (TW); Tze-Liang Lee, Hsinchu (TW)

(21) Appl. No.: 19/277,659

(22) Filed: Jul. 23, 2025

Related U.S. Application Data
(63) Continuation of application No. 18/348,868, filed on Jul. 7, 2023.
(60) Provisional application No. 63/488,858, filed on Mar. 7, 2023.

(51) Int. Cl. H10D 64/01; H01L 21/02; H01L 21/768; H10D 64/27; H10D 64/68

(52) U.S. Cl. CPC H10D 64/01; H01L 21/0217; H01L 21/0228; H01L 21/76802; H01L 21/76877; H10D 64/511; H10D 64/693

(57) ABSTRACT

A method for semiconductor fabrication includes forming a metal gate surrounded by a first silicon oxide layer, wherein a metallic surface of the metal gate is exposed. The method further includes selectively depositing a silicon nitride layer on the metallic surface and not on the first silicon oxide layer, and depositing a second silicon oxide layer on the first silicon oxide layer and on the silicon nitride layer.

### PRIORITY

This application is a continuation of U.S. patent application Ser. No. 18/348,868 filed Jul. 7, 2023, which claims the benefits of and priority to U.S. Prov. Pat. App. Ser. No. 63/488,858, filed Mar. 7, 2023, the entire disclosures of which are incorporated herein by reference.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling down has also increased the complexity of processing and manufacturing ICs.

For example, some semiconductor fabrication processes utilize high-k metal gates. In these processes, after the high-k metal gates are formed, an oxide film is typically deposited by plasma enhanced process and is used as interlayer dielectric (ILD) and passivation layer. Some oxygen-plasma species generated during the oxide film deposition may result in oxidation of the under-layer (e.g., the metal gates), which is undesirable. The present disclosure addresses this and other problems.

### BRIEF DESCRIPTION OF THE DRAWINGS

The present disclosure is best understood from the following detailed description when read with the accompanying figures. It is emphasized that, in accordance with the standard practice in the industry, various features are not drawn to scale and are used for illustration purposes only. In fact, the dimensions of the various features may be arbitrarily increased or reduced for clarity of discussion.

FIG. 1 is a simplified top view of a part of a semiconductor device such as an integrated circuit (IC), according to various aspects of the present disclosure.

FIGS. 2A and 2B show cross-sectional views of a portion of the semiconductor device of FIG. 1, in accordance with an embodiment.

FIGS. 3A and 3B show cross-sectional views of a portion of the semiconductor device of FIG. 1, in accordance with another embodiment.

FIG. 4A shows a flow chart of a method for forming the semiconductor device shown in FIG. 1, according to aspects of the present disclosure.

FIG. 4B illustrates a flow diagram of an atomic layer deposition (ALD) process utilized in the method in FIG. 4A, in accordance with an embodiment.

FIGS. 4C and 4D illustrate certain characteristic of the ALD process in FIG. 4B, in accordance with an embodiment.

FIGS. 5A, 5B, 6A, 6B, 7A, 7B, 8A, 8B, 9A, 9B, 10A, 10B, 11A, and 11B illustrate cross-sectional views of an embodiment of the semiconductor device in FIGS. 2A and 2B during a fabrication process according to the method of FIG. 4A, in accordance with some embodiment.

FIGS. 12A, 12B, 13A, 13B, 14A, 14B, 15A, 15B, 16A, 16B, 17A, 17B, 18A, and 18B illustrate cross-sectional views of an embodiment of the semiconductor device in FIGS. 3A and 3B during a fabrication process according to the method of FIG. 4A, in accordance with some embodiment.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. Still further, when a number or a range of numbers is described with “about,” “approximate,” and the like, the term is intended to encompass numbers that are within +/−10% of the number described, unless otherwise specified. For example, the term “about 5 nm” encompasses the dimension range from 4.5 nm to 5.5 nm.

This application relates generally to semiconductor fabrication processes and structures, and particularly to selectively depositing SiN (silicon nitride, e.g., Si₃N₄) on top of metal gates including high-k metal gates, thereby preventing or reducing oxidation of the metal gates. This provides multiple benefits, such as more stable metal gate operation, smooth source and drain (or source/drain or S/D) contact profile, and so on.

In some semiconductor fabrication processes that utilize metal gates, after the metal gates are formed, an oxide film may be deposited by plasma enhanced process and is used as an interlayer dielectric (ILD) and passivation layer. Some oxygen-plasma species generated during the oxide film deposition may undesirably cause oxidation of the underlying layers such as the metal gates. Such oxidation is undesirable because it may degrade the operations and performance of the underlying layers. One way to prevent such oxidation is to blanketly deposit (as opposed to selectively deposit) a SiN capping layer over the metal gates and any layer(s) (e.g., an ILD layer) surrounding the metal gates. With those methods, the etching processes used to form S/D contact holes may produce small lateral recesses (or small pockets) in the contact hole profile (which appear like dents into the sidewalls of the source/drain contact holes) when breaking through this SiN capping layer. Such recesses may be difficult to fill when forming S/D contacts, creating device reliability issues. As used herein, source/drain, or S/D, may refer to a source or a drain of a device. It may also refer to a region that provides a source and/or drain for multiple devices.

Some embodiments of the present disclosure resolve the above issues by selectively depositing a SiN capping layer only on top of the metal gates and not on the ILD layer surrounding the metal gates where S/D contact holes will be formed. In some embodiments, the SiN capping layer may extend partially or fully onto gate spacers on sidewalls of the metal gates. Beneficially, the etching processes used to form S/D contact holes do not break through this SiN capping layer and result in a smooth S/D contact hole profile, i.e., the sidewalls of the S/D contact holes extend continuously with a substantially constant angle from bottom of the S/D contact holes to top of the S/D contact holes. The smooth S/D contact holes make it easier for filling conductive material therein, and allow the S/D contacts to be formed with good integrity and reliability.

In an embodiment of the present disclosure, the selective SiN deposition is achieved by an Atomic Layer Deposition (ALD) process, which utilizes the characteristic that SiN nucleation takes longer time to occur on silicon oxide than on metal surfaces. In an embodiment, the ALD process includes cycling through four phases: a half-reaction self-limiting precursor adsorption phase, a purging phase, a half-reaction self-limiting co-reactant adsorption phase, and another purging phase. Utilizing the ALD process, about 3 nm to 5 nm thick SiN capping layer has been grown on metal surfaces and not on silicon oxide surfaces in some devices according to embodiments of the present disclosure. This and other features of the present disclosure are further discussed by referring to the accompanied figures.

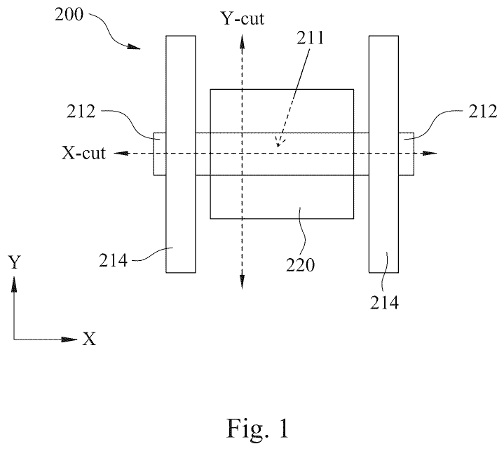

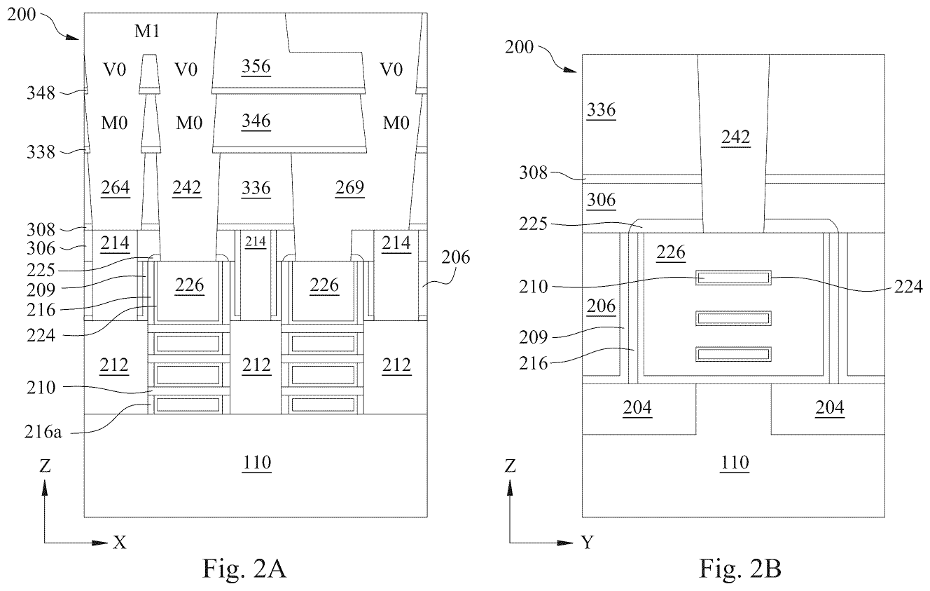

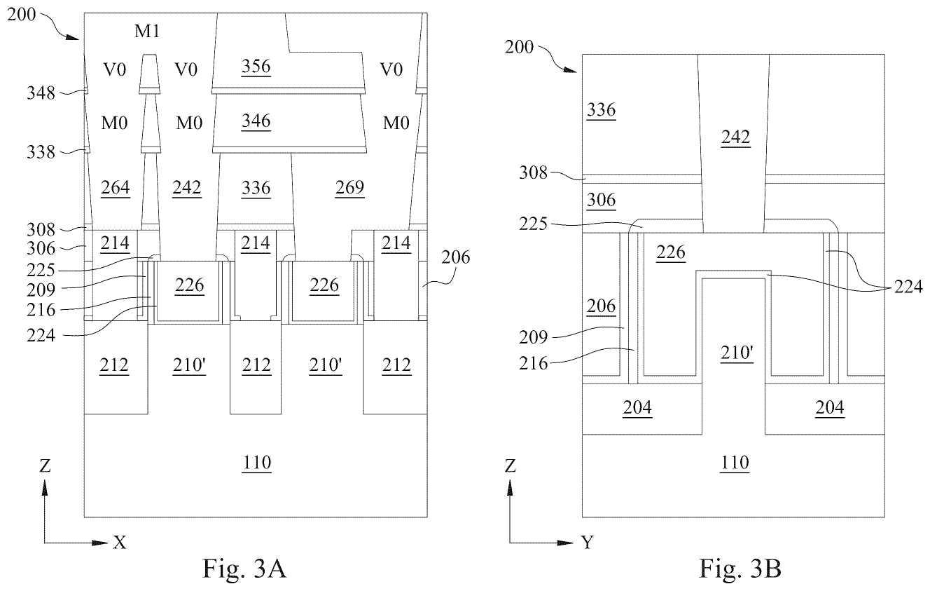

FIG. 1 shows a top view of a part of a semiconductor device 200, which may be an integrated circuit (IC). The device 200 is formed with, or formed on, a substrate 110 (shown in FIGS. 2A, 2B, 3A, and 3B), and may include gate-all-around (GAA) transistors, FinFETs, other transistors, or a combination thereof. As illustrated in FIG. 1, the device 200 includes a gate stack 220 engaging a channel region 211 of a semiconductor material and two S/D regions 212 on two sides of the gate stack 220. The device 200 further includes S/D contacts 214 disposed on and electrically connected to the S/D regions 212. Further details of the device 200 are shown in FIGS. 2A, 2B, 3A, and 3B according to two embodiments.

FIGS. 2A and 2B show two cross-sectional views of the device 200 along the X-cut line and Y-cut line in FIG. 1, respectively. The X-cut line is along a lengthwise direction of the channel region 211, and the Y-cut line is along a widthwise direction of the channel region 211. The device 200 in the embodiment illustrated in FIGS. 2A-2B includes one or more gate-all-around (GAA) transistors.

Referring to FIGS. 2A and 2B collectively, the device 200 is formed over a region of a substrate 110. The channel region 211 of the device 200 includes a stack of semiconductor layers 210 connecting the two S/D regions 212. The gate stack 220 includes a gate dielectric layer 224 and a metal gate electrode 226. The gate dielectric layer 224 may include a dielectric interfacial layer directly on the respective semiconductor layers 210 and one or more high-k dielectric layers on the interfacial layer. The device 200 further includes gate spacers 216 on sidewalls of the gate stack 220. Portions of the gate stack 220 are disposed vertically (along the Z direction) between two adjacent semiconductor layers 210. Inner spacers 216a are disposed laterally (along the X direction) between those portions of the gate stack 220 and the S/D regions 212. The gate spacers 216 and the inner spacers 216a may be formed at different process steps and may include same or different materials. In the embodiment depicted in FIGS. 2A and 2B, the device 200 further includes a contact etch stop (CES) layer 209 on top surfaces of the S/D regions 212 and on the sidewalls of the gate spacers 216. The device 200 further includes an isolation structure 204 and an interlayer dielectric (ILD) layer 206 over the substrate 110. The gate stack 220, the gate spacer 216, and the ILD layer 206 are disposed over the isolation structure 204. Further, the ILD layer 206 is disposed over the sidewalls of the gate spacer 216 and over the CES layer 209. In some embodiments, the CES layer 209 is omitted.

The device 200 further includes a capping layer 225 that is disposed on the metal gate electrode 226. In embodiments, the capping layer 225 is disposed directly on (i.e., in direct contact with) the top surface of the metal gate electrode 226. In the present embodiment, the capping layer 225 includes silicon nitride (e.g., Si₃N₄) and may be referred to as SiN capping layer 225. In some embodiments, the capping layer 225 may include SiCN, SiC, AlN, TaN, or other elements. In some embodiments, the capping layer 225 extends horizontally (along the X and Y directions) to cover not only the top surface of the metal gate electrodes 226 but also the top surface of the gate dielectric layer 224. In some further embodiments, the capping layer 225 extends horizontally (along the X and Y directions) to the top surface of the gate spacers 216. In those embodiments, the capping layer 225 fully covers the top surface of the metal gate electrodes 226 and the gate dielectric layer 224 and may partially or fully cover the top surface of the gate spacers 216. In yet further embodiments, the capping layer 225 extends horizontally (along the X and Y directions) to the top surface of the CES layer 209. In those further embodiments, the capping layer 225 fully covers the top surface of the metal gate electrode 226, the gate dielectric layer 224, and the gate spacers 216, and may partially or fully cover the top surface of the CES layer 209. In the embodiments depicted in FIGS. 2A-2B, the capping layer 225 is not disposed on the top surface of the ILD layer 206 which includes primarily silicon oxide (silicon dioxide). Further, in the embodiments depicted in FIGS. 2A-2B, the capping layer 225 has rounded corners on its ends in the X and Y directions. The rounded corners of the capping layer 225 may be disposed directly on the metal gate electrode 226, the gate dielectric layer 224, the gate spacers 216, or the CES layer 209 depending on the extent of the capping layer 225 as discussed in various embodiments above.

As shown in FIGS. 2A-2B, the device 200 further includes another ILD layer 306 on the ILD layer 206, the CES layer 209, the gate spacers 216, and the capping layer 225. The S/D contacts 214 penetrate through the ILD layer 306, the ILD layer 206, and the CEL layer 209 (when present) and are electrically connected to the S/D regions 212. The S/D contacts 214 are spaced from (i.e., without direct contact with) the capping layer 225. Each sidewall of the S/D contacts 214 extends continuously from bottom to top with a substantially constant angle. The device 200 further includes dielectric layers 308 and 336 on the ILD layer 306 and S/D vias 264 on S/D contacts 214. The device 200 further includes gate vias 242 that penetrate dielectric layers 336 and 308 and capping layer 225 and electrically contact the metal gate electrode 226. The device 200 further includes butted contacts 269 disposed over and connecting some of the S/D contacts 214 with some of the metal gate electrodes 226. The device 200 further includes various dielectric layers 338, 346, 348, and 356 on the dielectric layer 336 and a multi-layer interconnect structure embedded in these dielectric layers including metal lines M0, M1, vias V0, and other metal lines and vias (not shown). The semiconductor device 200 may include other features not shown in FIGS. 2A-2B.

FIGS. 3A and 3B show two cross-sectional views of the device 200 along the X-cut line and Y-cut line in FIG. 1, respectively, in another embodiment where the device 200 includes one or more FinFET transistors. The structure of the device 200 in this embodiment is substantially the same as that depicted in FIGS. 2A-2B except that the channel region 211 in this embodiment includes one or more semiconductor fins 210′ rather than a stack of semiconductor layers 210. The gate dielectric layer 224 and the metal gate electrode 226 in this embodiment are disposed on top and sidewalls of the semiconductor fins 210′.

The various elements of the device 200 are further described below. The substrate 110 is a silicon substrate in the present embodiment. Alternatively, the substrate 110 may comprise another elemental semiconductor, such as germanium; a compound semiconductor including silicon carbide, gallium arsenide, gallium phosphide, indium phosphide, indium arsenide, and indium antimonide; an alloy semiconductor including silicon germanium, gallium arsenide phosphide, aluminum indium phosphide, aluminum gallium arsenide, gallium indium arsenide, gallium indium phosphide, and gallium indium arsenide phosphide; or combinations thereof.

The isolation structure 204 may comprise silicon oxide, silicon nitride, silicon oxynitride, fluorosilicate glass (FSG), a low-k dielectric material, and/or other suitable insulating material. The isolation structure 204 may include shallow trench isolation (STI) structures. Other isolation structures such as field oxide, LOCal Oxidation of Silicon (LOCOS), and/or other suitable structures are possible. The isolation structure 204 may include a multi-layer structure, for example, having a non-conformal oxide layer over one or more thermal oxide liner layers.

The ILD layers 206 and 306 may include a dielectric material such as silicon oxide or primarily silicon oxide. Alternatively, or additionally, the ILD layers 206 and 306 may include silicon nitride, silicon oxynitride, TEOS formed oxide, SiH₄ formed oxide, phosphosilicate glass (PSG), low-k dielectric material, other suitable dielectric material, or combinations thereof.

The semiconductor layers 210 and the semiconductor fins 210′ may include single crystalline silicon. Alternatively, the semiconductor layers 210 and the semiconductor fins 210′ may comprise germanium, silicon germanium, or another suitable semiconductor material(s). The S/D regions 212 may include epitaxially grown semiconductor material(s) with proper n-type or p-type dopants. For example, the S/D regions 212 may include silicon and may be doped with carbon, phosphorous, arsenic, other n-type dopant, or combinations thereof (for example, forming Si: C epitaxial source/drain features, Si: P epitaxial source/drain features, or Si: C: P epitaxial source/drain features). Alternatively, the S/D regions 212 may include silicon germanium or germanium and may be doped with boron, other p-type dopant, or combinations thereof (for example, forming Si: Ge: B epitaxial source/drain features).

The gate dielectric layer 224 may include an interfacial layer and a high-k dielectric layer. The interfacial layer may include SiO₂, HfSiO, SiON, other silicon-comprising dielectric material, other suitable dielectric material, or combinations thereof. The high-k dielectric layer may include HfO₂, HfSiO, HfSiO₄, HfSiON, HfLaO, HfTaO, HfTiO, HfZrO, HfAlOx, ZrO, ZrO₂, ZrSiO₂, AlO, AlSiO, Al₂O₃, TiO, TiO₂, LaO, LaSiO, Ta₂O₃, Ta₂O₅, Y₂O₃, SrTiO₃, BaZrO, BaTiO₃ (BTO), (Ba,Sr)TiO₃ (BST), Si₃N₄, hafnium dioxide-alumina (HfO₂—Al₂O₃) alloy, other suitable high-k dielectric material, or combinations thereof. High-k dielectric material generally refers to dielectric materials having a high dielectric constant, for example, greater than that of silicon oxide (k≈3.9).

The metal gate electrodes 226 may include a work function metal layer and a bulk metal layer. The work function metal layer can be an n-type work function metal or a p-type work function metal. P-type work function layer includes any suitable p-type work function material, such as TiN, TaN, TaSN, Ru, Mo, Al, WN, WCN ZrSi₂, MoSi₂, TaSi₂, NiSi₂, other p-type work function material, or combinations thereof. N-type work function layer includes any suitable n-type work function material, such as Ti, Al, Ag, Mn, Zr, TiAl, TiAlC, TiAlSiC, TaC, TaCN, TaSiN, TaAl, TaAlC, TaSiAlC, TiAlN, other n-type work function material, or combinations thereof. The bulk metal layer includes a suitable conductive material, such as Co, Al, W, and/or Cu. The bulk metal layer may additionally or collectively include other metals, metal oxides, metal nitrides, other suitable materials, or combinations thereof.

The gate spacers 216 and inner spacers 216a may include a dielectric material having silicon, oxygen, carbon, nitrogen, other suitable material, or combinations thereof (e.g., silicon oxide, silicon nitride, silicon oxynitride (SiON), silicon carbide, silicon carbon nitride (SiCN), silicon oxycarbide (SiOC), silicon oxycarbon nitride (SiOCN)).

The dielectric layers 336, 346, and 356 may include a material like that in the ILD layer 206. For example, the dielectric layers 336, 346, and 356 may include a dielectric material such as silicon oxide, TEOS formed oxide, phosphosilicate glass (PSG), low-k dielectric material, other suitable dielectric material, or combinations thereof.

The CES layer 209 may include a material different than the ILD layer 206. For example, where the ILD layer 206 includes a low-k dielectric material, the CES layer 209 may include silicon and nitrogen, such as silicon nitride or silicon oxynitride. The dielectric layers 308, 338, and 348 may include a dielectric material like that in the CES layer 209. The dielectric layers 308, 338, and 348 may also function as etch stop layer when the layers 336, 346, and 356, respectively, are etched.

The S/D contacts 214 include a conductive material, such as metal. Suitable metals for the S/D contacts 214 include aluminum, aluminum alloy (such as aluminum/silicon/copper alloy), copper, copper alloy, titanium, titanium nitride, tantalum, tantalum nitride, tungsten, polysilicon, metal silicide, other suitable metals, or combinations thereof. The metal silicide may include nickel silicide, cobalt silicide, tungsten silicide, tantalum silicide, titanium silicide, platinum silicide, erbium silicide, palladium silicide, or combinations thereof. The S/D contacts 214 may include a conductive barrier layer and a conductive fill layer over the conductive barrier layer.

Each of the vias (including S/D contact vias 264, gate vias 242, V0), butted contacts 269, and metal lines (including M0 and M1) may include a conductive barrier layer and a metal fill layer over the conductive barrier layer. The conductive barrier layer may include titanium (Ti), tantalum (Ta), tungsten (W), cobalt (Co), ruthenium (Ru), or a conductive nitride such as titanium nitride (TiN), titanium aluminum nitride (TiAlN), tungsten nitride (WN), tantalum nitride (TaN), or combinations thereof. The metal fill layer may include tungsten (W), cobalt (Co), molybdenum (Mo), ruthenium (Ru), or other metals.

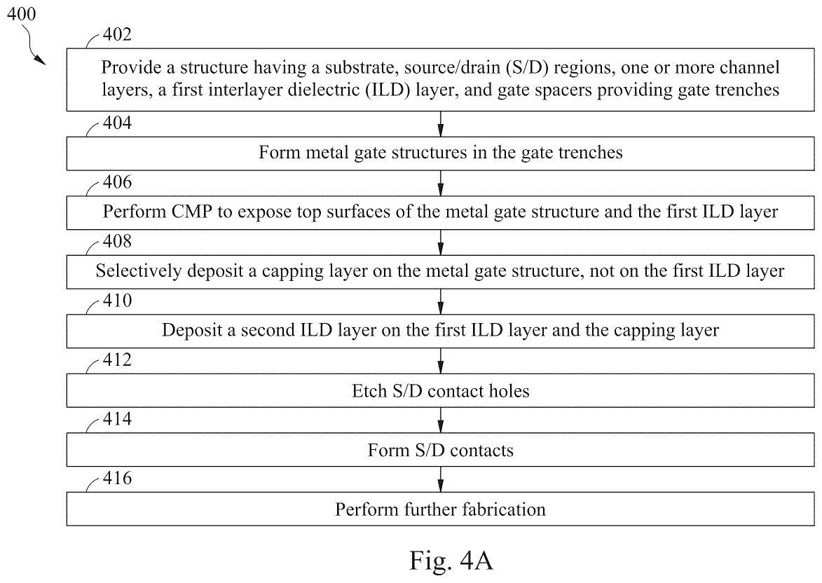

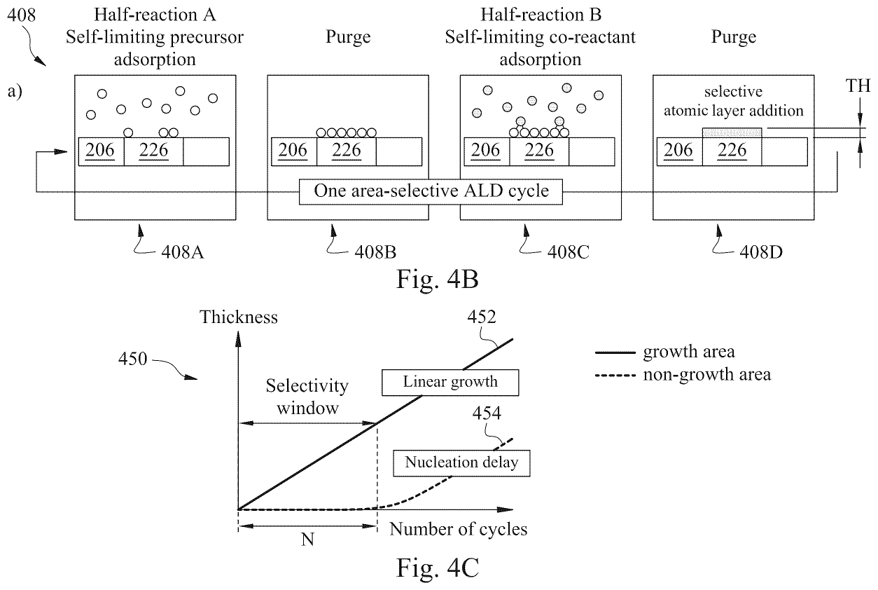

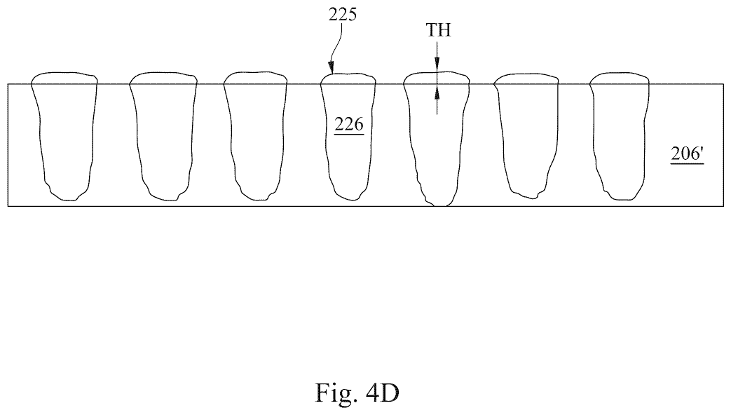

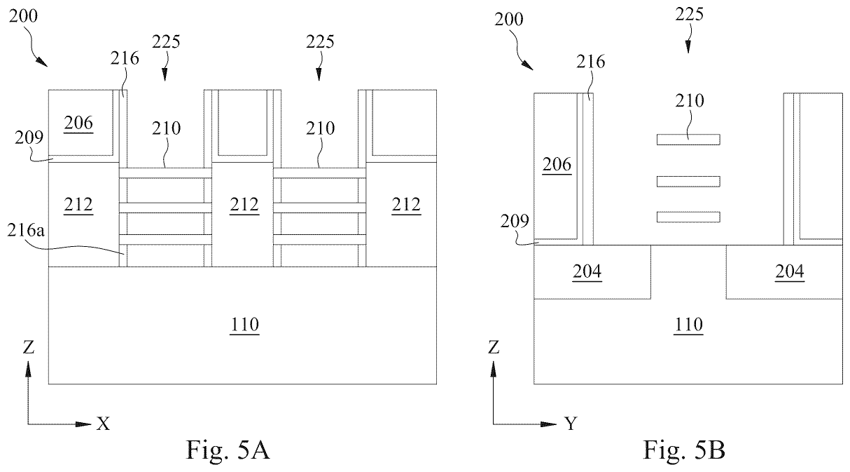

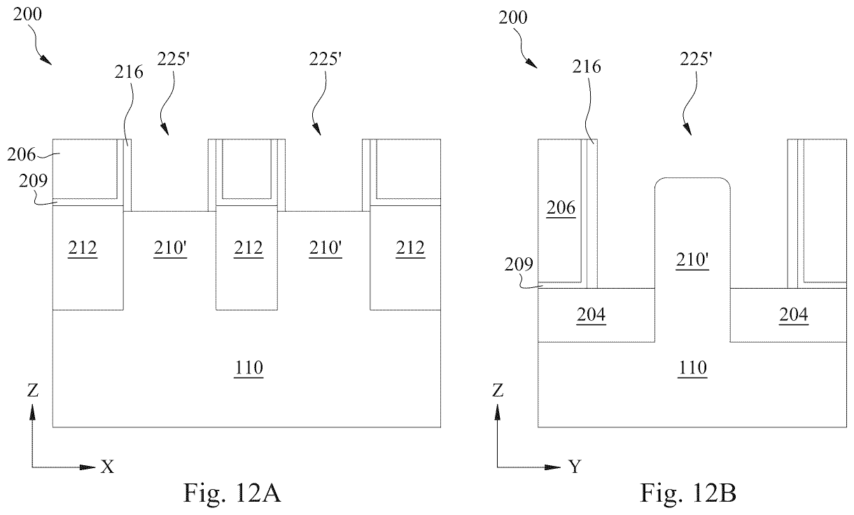

FIG. 4A illustrates a flow chart of a method 400 for forming the semiconductor device 200, in accordance with some embodiments. The method 400 is merely an example and is not intended to limit the present disclosure beyond what is explicitly recited in the claims. Additional operations can be provided before, during, and after the method 400, and some operations described can be replaced, eliminated, or moved around for additional embodiments of the method. The method 400 is described below in conjunction with FIGS. 5A-11B and FIGS. 12A-18B that illustrate various cross-sectional views of the semiconductor device 200 during fabrication steps according to the method 400. More specifically, FIGS. 5A, 6A, 7A, 8A, 9A, 10A, and 11A illustrate cross-sectional views of the semiconductor device 200 according to the embodiment shown in FIGS. 2A-2B along the X-cut line in FIG. 1; FIGS. 5B, 6B, 7B, 8B, 9B, 10B, and 11B illustrate cross-sectional views of the semiconductor device 200 according to the embodiment shown in FIGS. 2A-2B along the Y-cut line in FIG. 1; FIGS. 12A, 13A, 14A, 15A, 16A, 17A, and 18A illustrate cross-sectional views of the semiconductor device 200 according to the embodiment shown in FIGS. 3A-3B along the X-cut line in FIG. 1; and FIGS. 12B, 13B, 14B, 15B, 16B, 17B, and 18B illustrate cross-sectional views of the semiconductor device 200 according to the embodiment shown in FIGS. 3A-3B along the Y-cut line in FIG. 1.

At operation 402, the method 400 provides, or is provided with, the semiconductor device 200 in an intermediate fabrication state, such as shown in FIGS. 5A-5B and 12A-12B. Referring to FIGS. 5A-5B, the semiconductor device 200 includes S/D regions 212, a stack of semiconductor layers 210, gate spacers 216, inner spacer 216a, CES layer 209, and ILD layer 206 as described with reference to FIGS. 2A and 2B. The semiconductor device 200 further includes gate trenches 225 between pairs of laterally opposing gate spacers 216 and between pairs of laterally opposing inner spacers 216a. The semiconductor layers 210 are exposed in the gate trenches 225. In an embodiment, the gate trenches 225 are resulted from processes that remove sacrificial gate stacks between the gate spacers 216 and processes that remove sacrificial semiconductor layers vertically between the semiconductor layers 210. Referring to FIGS. 12A-12B, the semiconductor device 200 includes S/D regions 212, semiconductor fin(s) 210′, gate spacers 216, inner spacer 216a, CES layer 209, and ILD layer 206 as described with reference to FIGS. 3A and 3B. The semiconductor device 200 further includes gate trenches 225′ between pairs of laterally opposing gate spacers 216. The semiconductor fin(s) 210′ are exposed in the gate trenches 225′. In an embodiment, the gate trenches 225′ are resulted from processes that remove sacrificial gate stacks between the gate spacers 216.

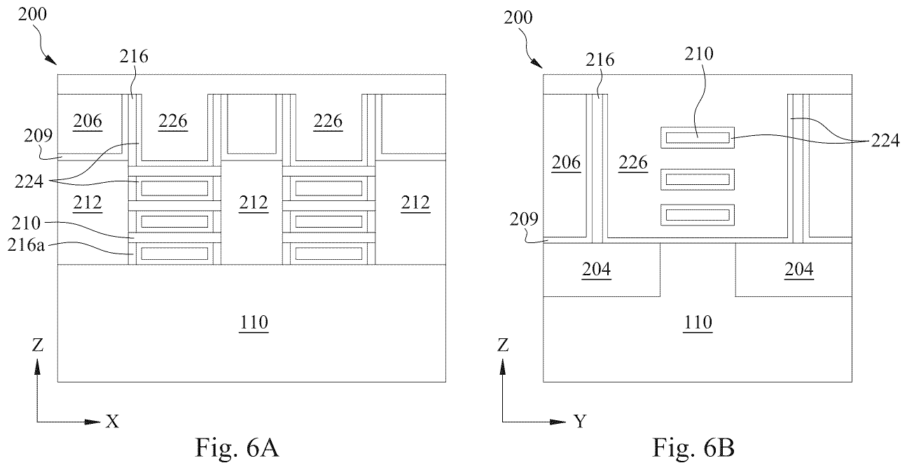

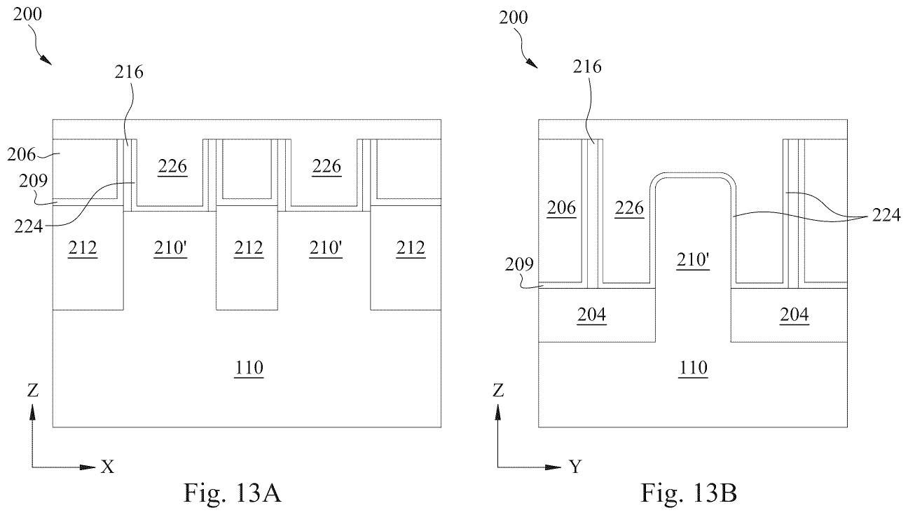

At operation 404, the method 400 forms gate dielectric layer 224 and metal gate electrode 226 in the gate trenches 225 such as shown in FIGS. 6A-6B or in the gate trenches 225′ such as shown in FIGS. 13A-13B. Referring to FIGS. 6A-6B, the gate dielectric layer 224 is deposited to wrap around each of the semiconductor layers 210, on a top surface of the substrate 110, on a top surface of the isolation structure 204, and on sidewalls of the gate spacers 216 and inner spacers 216a. Referring to FIGS. 13A-13B, the gate dielectric layer 224 is deposited on top and sidewalls of the semiconductor fins 210′, on a top surface of the substrate 110, on a top surface of the isolation structure 204, and on sidewalls of the gate spacers 216. Then, in both embodiments, the metal gate electrodes 226 are deposited over the gate dielectric layer 224 and fill the rest of the gate trenches 225 and 225′ respectively. Further, one or more metal layers of the metal gate electrodes 226 overfill the respective gate trenches 225 and 225′ and are deposited on the top surfaces of the gate spacers 216, the CES layer 209, and the ILD layer 206. The gate dielectric layer 224 may be formed by one or more processes, including chemical oxidation, thermal oxidation, ALD, chemical vapor deposition (CVD), and/or other suitable methods. The metal gate electrodes 226 may be formed by CVD, physical vapor deposition (PVD), plating, and/or other suitable processes.

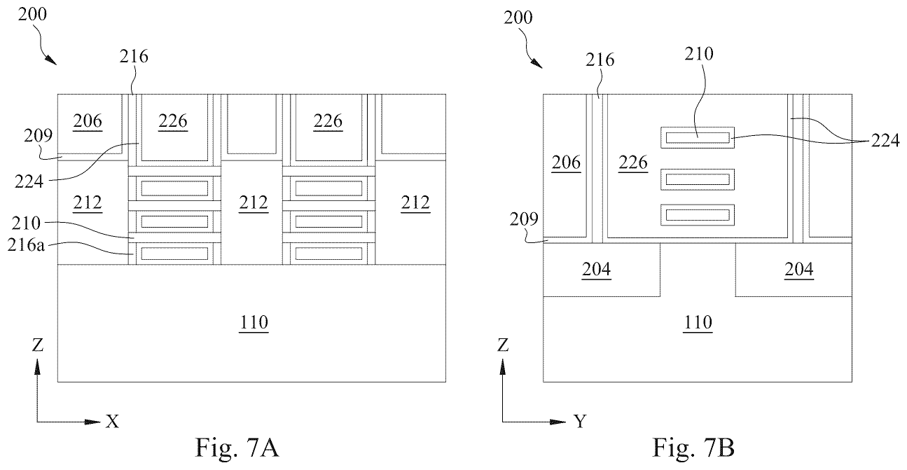

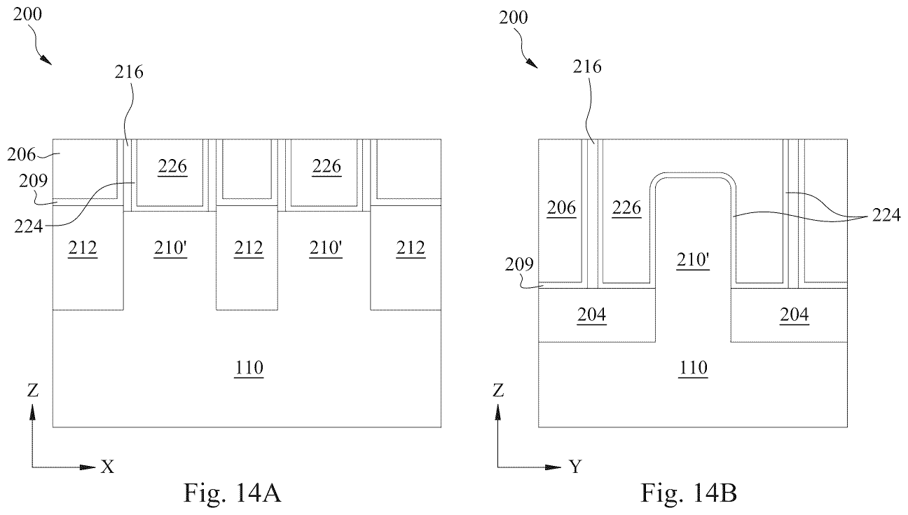

At operation 406, the method 400 performs a planarization process, such as chemical mechanical planarization (CMP), to the semiconductor device 200. The planarization process removes the one or more metal layers of the metal gate electrodes 226 from the top surfaces of the gate spacers 216, the CES layer 209, and the ILD layer 206. As a result, the top surfaces of the gate spacers 216, the CES layer 209, and the ILD layer 206, as well as the top surfaces of the gate dielectric layers 224 and the metal gate electrodes 226 are exposed such as shown in FIGS. 7A-7B and 14A-14B. These surfaces are substantially coplanar as a result of the planarization process. In some embodiments, the ILD layer 206 may be used as an end stop for the planarization process.

In some approaches, an oxide film may be deposited onto the top surfaces of the gate spacers 216, the CES layer 209, the ILD layer 206, the gate dielectric layers 224 and the metal gate electrodes 226 by a plasma enhanced process, such as plasma enhanced CVD. Some oxygen-plasma species generated during the oxide film deposition may undesirably cause oxidation of the underlying layers such as the metal gate electrodes 226. One way to prevent such oxidation is to blanketly deposit a SiN capping layer over the top surfaces of the gate spacers 216, the CES layer 209, the ILD layer 206, the gate dielectric layers 224, and the metal gate electrodes 226 prior to the oxide film deposition. However, that may introduce undesirable effects when forming S/D contacts at a later stage, such as creating lateral pockets in S/D contact holes. In the present embodiment, a SiN capping layer is selectively deposited onto the metal gate electrodes 226 and not onto the ILD layer 206, as will be discussed at operation 408. This not only prevents oxidation to the metal gate electrodes 226 but also provides benefits when forming S/D contacts, such as allowing smooth S/D contact hole profile to be easily formed.

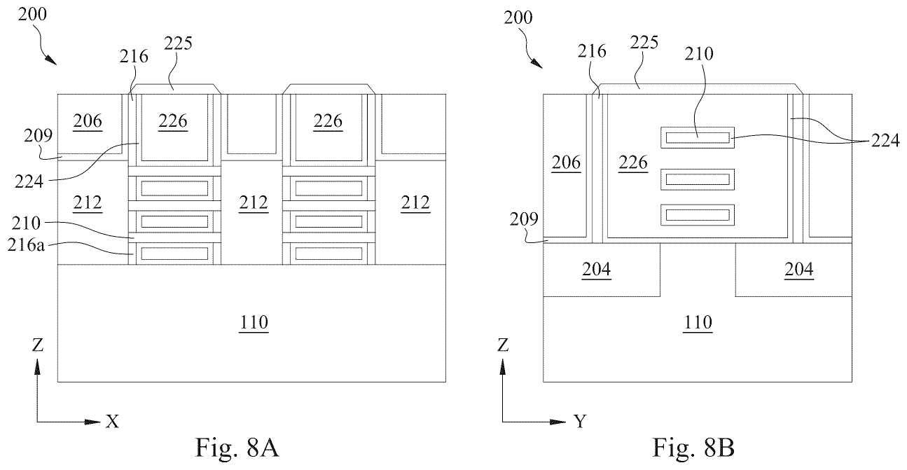

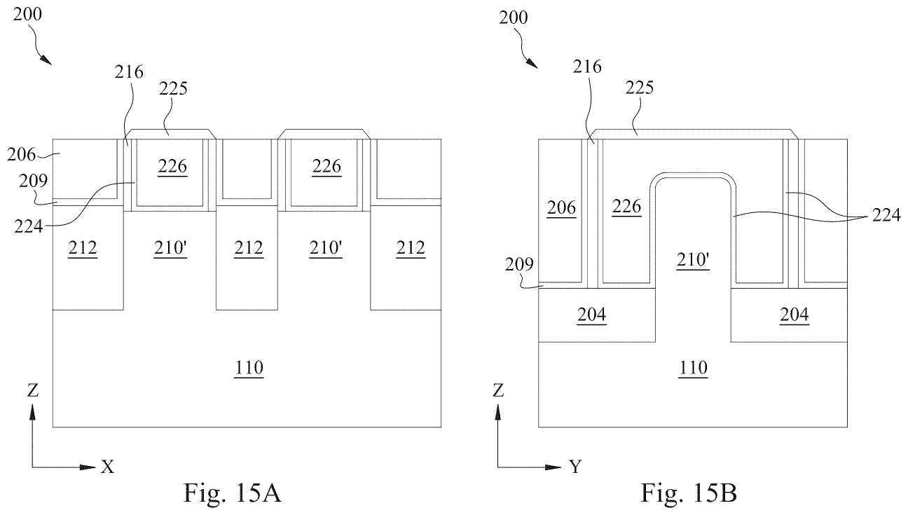

At operation 408, the method 400 selectively deposits a capping layer 225 onto the top surface of the metal gate electrodes 226 and not onto the top surface of the ILD layer 206, such as shown in FIGS. 8A-8B and 15A-15B. In an embodiment, the capping layer 225 includes, or includes primarily, silicon nitride (Si₃N₄), and the top surface of the ILD layer 206 includes, or includes primarily, silicon oxide (SiO₂). To further this embodiment, the selective deposition of the capping layer 225 is achieved by an ALD process where the silicon nitride nucleation on silicon oxide surfaces is delayed relative to the silicon nitride nucleation on metallic surfaces. Thus, by controlling the ALD process's duration and nucleation cycles, the capping layer 225 (having silicon nitride for example) can be selectively deposited onto the top surface of the metal gate electrodes 226 (which is metallic) and not onto the top surface of the ILD layer 206 (which is primarily silicon oxide for example).

This is further illustrated in FIGS. 4B and 4C. Referring to FIG. 4B, in an embodiment, the operation 408 includes an ALD process having four phases in each ALD cycle. The four phases are designated with 408A, 408B, 408C, and 408D.

The phase 408A is a precursor adsorption phase. During the phase 408A, a precursor for the material in the capping layer 225 is introduced into an ALD reaction chamber where the semiconductor device 200 is held. Atoms and/or particles of the precursor are adsorbed onto the metallic surface of the metal gate electrodes 226. A bond develops between the atoms and/or particles of the precursor and the metallic surface of the metal gate electrodes 226 to a degree that it is strong enough to withstand the physical force of the purging that occurs during the phase 408B. Also, during the phase 408A, atoms or particles of the precursor are not adsorbed onto the silicon oxide surface of the ILD layer 206. In some instances, some atoms or particles of the precursor may fall onto the silicon oxide surface of the ILD layer 206 but they are not sufficiently bonded to the silicon oxide surface of the ILD layer 206 and can be purged by the physical force of the purging that occurs during the phase 408B. In an embodiment, the duration of the phase 408A is controlled to achieve the above results. For example, the duration of the phase 408A may be controlled to be in a range from 0.1 second to 5 seconds such as from 0.1 second to 3 seconds or from 0.2 second to 3 seconds. If the duration of the phase 408A is greater than 5 seconds, then some atoms or particles of the precursor will adsorb onto the silicon oxide surface of the ILD layer 206 and would be sufficiently bonded thereon. If the duration of the phase 408A is less than 0.1 second, then it may not be sufficient for atoms or particles of the precursor to be adsorbed onto the metallic surface of the metal gate electrodes 226. Neither case (i.e., outside of the designed duration range) is desirable for the selective deposition of the capping layer 225. In an embodiment, the precursor used in the phase 408A may be or may include SiH₂Cl₂ (DCS), SiH₂I₂ (diiodosilane), other precursors providing Si (silicon), or a combination thereof. In an embodiment, the phase 408A may be performed at a pressure in a range from 0.5 Torr to 30 Torr and at a temperature in a range from 250° C. to 500° C.

The phase 408B is a purging phase. During the phase 408B, a purging gas, such as N₂, Ar, H₂, or a mixture thereof, is supplied into (or flowed into) the reaction chamber where the semiconductor device 200 is held. The purging gas is supplied with sufficient force to remove any non-adsorbed atoms and/or particles of the precursor from the reaction chamber. In an embodiment, the flow rate of the purging gas may be controlled to be in a range from 0.5 slm to 40 slm (standard liter per minute). This range is designed such that it provides a physical force sufficiently strong to remove non-adsorbed atoms and/or particles of the precursor from the reaction chamber and remove any atoms and/or articles particles of the precursor from the surface of the ILD layer 206, but not remove atoms and/or particles of the precursor that are adsorbed onto the metallic surface of the metal gate electrodes 226. In an embodiment, duration for the phase 408B may be controlled to be in a range from 0.5 second to 10 seconds.

The phase 408C is a co-reactant adsorption phase. During the phase 408C, a co-reactant for the material in the capping layer 225 is introduced into the reaction chamber. Atoms and/or particles of the co-reactant are adsorbed onto and react with atoms and/or particles of the precursor that are adsorbed onto the metallic surface of the metal gate electrodes 226 during the phase 408A. The reaction between the precursor and the co-reactant produces a layer of the material in the capping layer 225. Also, during the phase 408C, atoms or particles of the co-reactant are not adsorbed onto the silicon oxide surface of the ILD layer 206. In some instances, some atoms or particles of the co-reactant may fall onto the silicon oxide surface of the ILD layer 206 but they are not sufficiently bonded to the silicon oxide surface of the ILD layer 206 and can be purged by the physical force of the purging that occurs during the phase 408D. In an embodiment, the duration of the phase 408C is controlled to achieve the above results. For example, the duration of the phase 408C may be controlled to be in a range from 3 seconds to 10 seconds such as from 3 seconds to 8 seconds or from 5 seconds to 7 seconds. If the duration of the phase 408C is greater than 10 seconds, then some atoms or particles of the co-reactant will adsorb onto the silicon oxide surface of the ILD layer 206 and would be sufficiently bonded thereon. If the duration of the phase 408C is less than 3 seconds, then it may not be sufficient for atoms or particles of the co-reactant to be adsorbed onto the atoms and/or particles of the precursor. Neither case (i.e., outside the designed duration range) is desirable for the selective deposition of the capping layer 225. In an embodiment, the co-reactant used in the phase 408C may be or may include NH₃, N₂, a mixture of NH₃ and H₂, other co-reactant providing N (nitrogen), or a combination thereof. In an embodiment, the phase 408C may be performed at a pressure in a range from 0.5 Torr to 30 Torr and at a temperature in a range from 250° C. to 500° C.

The phase 408D is another purging phase. During the phase 408D, a purging gas, such as Ar, N₂, H₂, or a mixture thereof, is supplied into (or flowed into) the reaction chamber. The purging gas is supplied with sufficient force to remove any non-adsorbed atoms and/or particles of the co-reactant from the reaction chamber. In an embodiment, the flow rate of the purging gas may be controlled to be in a range from 0.5 slm to 30 slm. This range is designed such that it provides a physical force sufficiently strong to remove non-adsorbed atoms and/or particles of the co-reactant from the reaction chamber and remove any atoms and/or particles of the co-reactant from the surface of the ILD layer 206, but not remove atoms and/or particles of the co-reactant and the precursor that are adsorbed onto the metallic surface of the metal gate electrodes 226. In an embodiment, duration for the phase 408D may be controlled to be in a range from 0.5 second to 20 seconds.

The operation 408 may repeat the phases 408A, 408B, 408C, and 408D to deposit the capping layer 225 selectively on the surface of the metal gate electrodes 226 without depositing on the surface of the ILD layer 206. FIG. 4C shows a graph 450 that illustrates the relation between the number of ALD cycles (horizontal axis) and the thickness of the capping layer deposited on two different surfaces (the vertical axis), which is the case in operation 408. Particularly, line 452 illustrates that the thickness of the capping layer 225 deposited on a metallic surface (such as the top surface of the metal gate electrodes 226) grows linearly as the number of ALD cycles increases. Further, line 454 illustrates that the thickness of the capping layer 225 deposited on a silicon oxide surface (such as the top surface of the ILD layer 206) is initially 0 (no deposition) and remains 0 until “N” ALD cycles later. After the “N” ALD cycles, the capping layer 225 grows on both surfaces linearly (or almost linearly) as the number of ALD cycles increases. In other words, the number of cycles that can be repeated in the ALD process in operation 408 without depositing the capping layer 255 on the ILD layer 206 is “N.” When the number of ALD cycles exceeds N, the capping layer 225 will be deposited onto the top surface of the ILD layer 206 in addition to the top surface of the metal gate electrode 226. In some embodiments, the number N is in a range from 15 to 300. In some embodiments of the operation 408, the capping layer 225 is deposited to a thickness TH in a range from about 3 nm to about 5 nm, which is within the N cycles of the ALD process.

FIG. 4D shows examples of capping layer 225 deposited onto top surfaces of metal gate electrodes 226 that are surrounded by a film 206′. The film 206′ includes primarily silicon oxide (or silicon dioxide), similar to the ILD layer 206. As shown in FIG. 4D, the capping layer 225 has a shape that is thicker in the middle section and becomes gradually thinner towards both ends. The thickness TH (also illustrated in FIGS. 4B and 4C) as measured in the middle section is about 3 nm to about 5 nm. As shown in FIG. 4D, the capping layer 225 is not deposited onto the surface of the film 206′.

Referring to FIGS. 8A-8B and 15A-15B, in some embodiments, the capping layer 225 extends horizontally (along the X and Y directions) to cover not only the top surface of the metal gate electrodes 226 but also the top surface of the gate dielectric layer 224. In some further embodiments, the capping layer 225 fully covers the top surface of the metal gate electrode 226 and the gate dielectric layer 224 and may partially or fully cover the top surface of the gate spacers 216. In yet further embodiments (not shown), the capping layer 225 extends horizontally (along the X and Y directions) to the top surface of the CES layer 209. Further, in the embodiments depicted in in FIGS. 8A-8B and 15A-15B, the capping layer 225 has rounded corners on its ends in the X and Y directions. The rounded corners of the capping layer 225 may be disposed directly on the metal gate electrode 226, the gate dielectric layer 224, the gate spacers 216, or the CES layer 209 depending on the extent of the capping layer 225 as discussed in various embodiments above. The rounded corners may be formed as a result of the metallic surface limiting the initial nucleation of the capping layer 225.

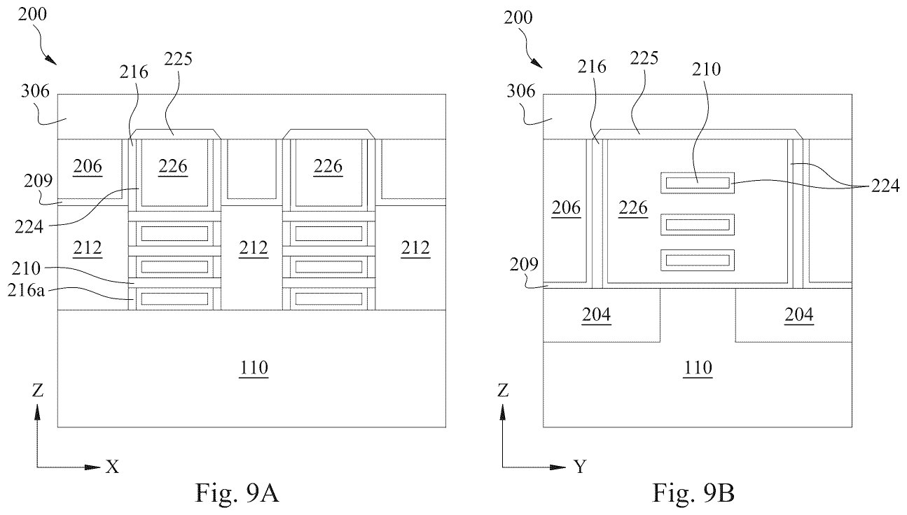

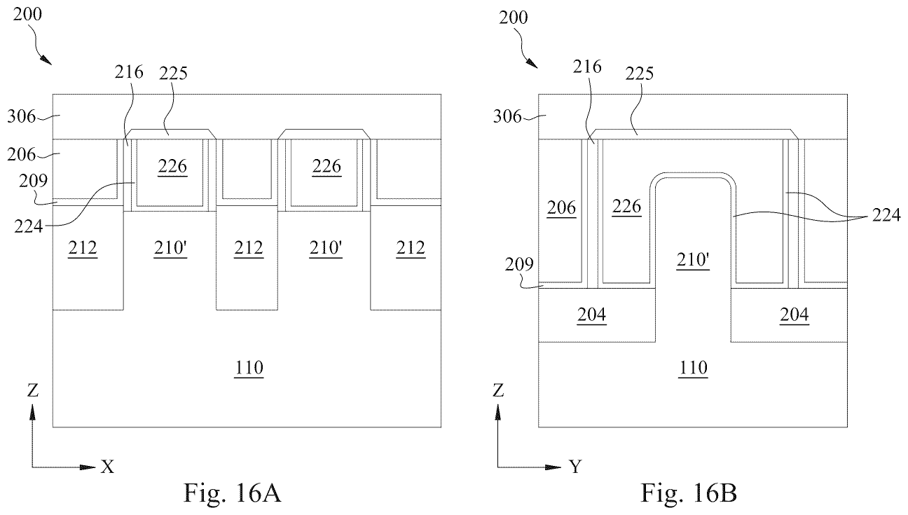

At operation 410, the method 400 deposits another ILD layer 306 over the ILD layer 206, the capping layer 225, the CES layer 206, the gate spacers 216, the gate dielectric layer 224, and the metal gate electrodes 226, such as shown in FIGS. 9A-9B and 16A-16B. The ILD layer 306 may include a dielectric material such as silicon oxide, TEOS formed oxide, phosphosilicate glass (PSG), low-k dielectric material, other suitable dielectric material, or combinations thereof. In an embodiment, the ILD layer 306 and the ILD layer 206 include the same material so that S/D contact hole etching process is simplified. The ILD layer 306 may be deposited using plasma enhanced CVD or other suitable methods. Because of the capping layer 225, deposition of the ILD layer 306 does not oxidize the top surface of the metal gate electrodes 226, ensuring good reliability and performance of the metal gate electrodes 226. After the ILD layer 306 is deposited, a planarization process (e.g., CMP) may be performed to planarize the top surface of the ILD layer 306.

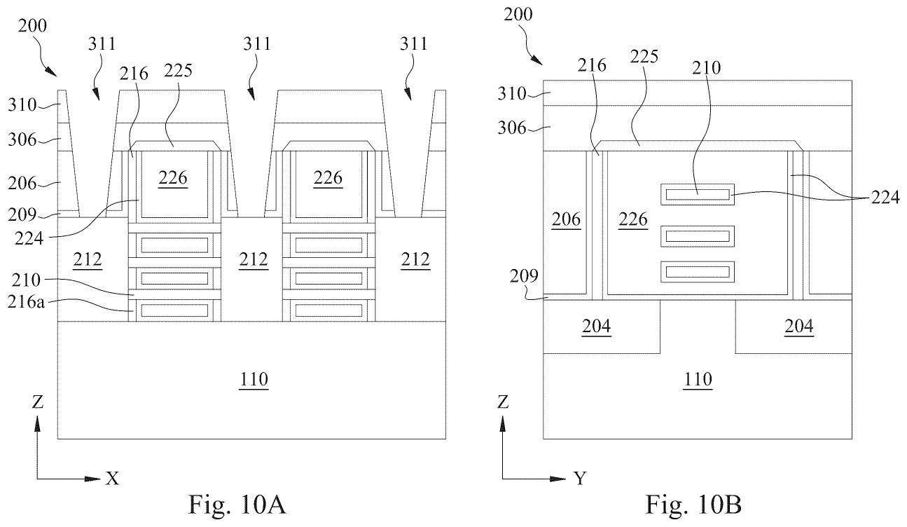

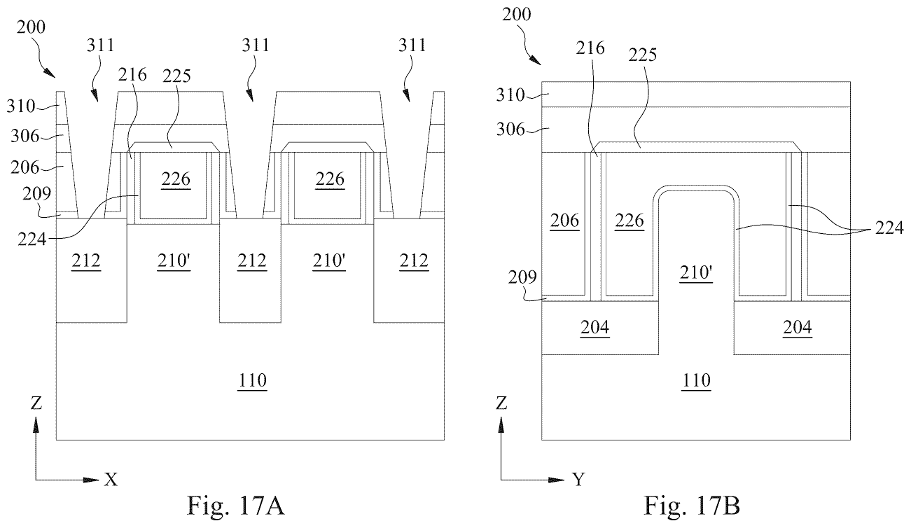

At operation 412, the method 400 forms S/D contact holes in the semiconductor device 200. This may involve multiple processes including photolithography, patterning, and etching. For example, operation 412 may form a hard mask 310 over the ILD layer 306, as shown in FIGS. 10A-10B and 17A-17B. Then, operation 412 may form a photoresist layer (not shown) over the hard mask 310, for example, by spin coating. Next, operation 412 patterns the photoresist layer using a photolithography process to form a patterned photoresist and etches the hard mask 310 through the patterned photoresist, thereby forming a patterned hard mask 310. Subsequently, operation 412 etches the ILD layers 306 and 206 through at least the patterned hard mask 310, thereby forming S/D contact holes 311 in the semiconductor device 200 to expose the S/D regions 212. In embodiments where the semiconductor device 200 includes the CES layer 209, operation 412 may perform multiple etches. For example, operation 412 may first etch the ILD layers 306 and 206 and stop on CES layer 209, and then etch the CES layer 209 to expose the S/D regions 212. For this purpose, the CES layer 209 includes a different material than those in the ILD layers 306 and 206. Having CES layer 209 may beneficially allow S/D contact holes 311 in different areas of the semiconductor device 200 (e.g., in both dense and sparse areas) to be etched with substantially the same depth.

As shown in FIGS. 10A and 17A, the S/D contact holes 311 are etched away from the capping layer 225 and do not expose the capping layer 225. Even in cases where the S/D contact holes 311 are inadvertently misaligned and located directly above a portion the capping layer 225, the etching process in operation 412 that is designed to etch the ILD layer 306/206 (which include primarily silicon oxide, for example) does not break through the capping layer 225 (which includes primarily silicon nitride, for example). Therefore, the capping layer 225 provides additional benefits of protecting the metal gate electrodes 226 from being inadvertently etched during S/D contact hole etching processes.

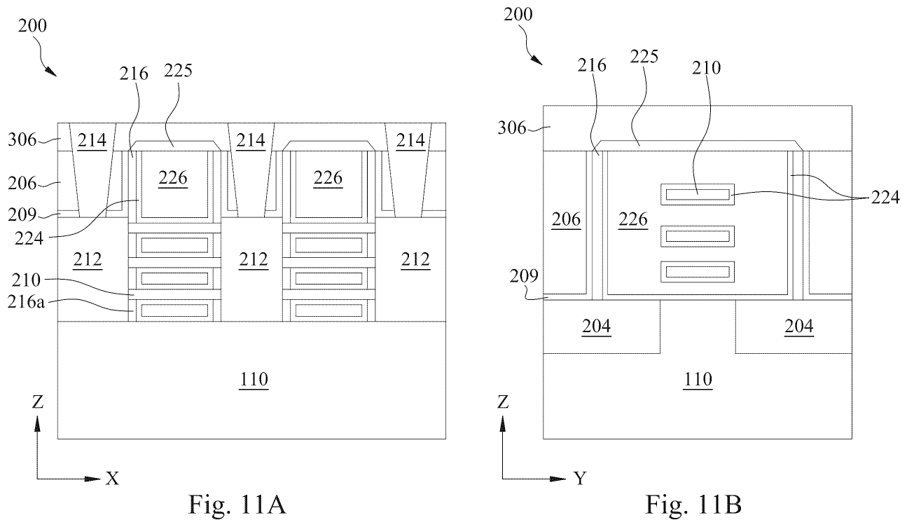

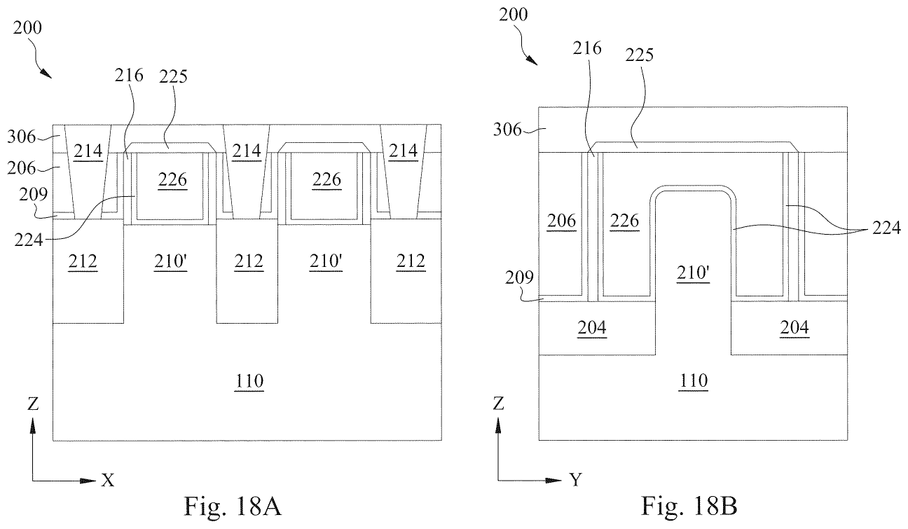

Further, in approaches where a silicon nitride layer is blanketly deposited over the metal gate electrodes 226 and the ILD layer 206, the S/D contact hole etching process would need to break through this blanket silicon nitride layer after the ILD layer 306 is etched. This might involve switching etchants or plasma species selective to different materials (silicon oxide vs silicon nitride), which is not as simple as the embodiment herein where the ILD layers 306 and 206 include same material, such as silicon oxide. Still further, breaking through the blanket silicon nitride layer sometimes produces lateral recesses (or pockets) between the ILD layer 306 and the ILD layer 206. Those lateral recesses are difficult to fill when forming S/D contacts 214 (in FIGS. 11A, 18A) and would degrade the reliability of the devices. In contrast, in the present embodiment, because the ILD layer 306 and ILD layer 206 include about the same material (e.g., both having primarily silicon dioxide) and there is no intermediate layer with a different material between the ILD layers 206 and 306, the S/D contact holes 311 can be etched to have smooth sidewalls. As shown in FIGS. 10A and 17A, the S/D contact holes 311 have sidewalls that extend at a constant or substantially constant angle from bottom of the contact holes to the top of the contact holes. Such smooth profile makes it easy to fill conductive material in the S/D contact holes 311.

At operation 414, the method 400 forms S/D contacts 214 in the S/D contact holes 311, such as shown in FIGS. 11A and 18A. In an embodiment, operation 414 includes depositing one or more conductive materials (such as a conductive barrier layer and a conductive fill layer) into the S/D contact holes 311, and then performing a planarization process (such as CMP) to the one or more conductive materials. The hard mask 310 may be removed prior to depositing the one or more conductive materials or may be removed during the planarization process. The one or more conductive materials remaining in the S/D contact holes 311 after the planarization process become the S/D contacts 214. In some embodiment, operation 414 includes forming a silicide layer on the S/D regions 212 prior to forming the S/D contacts 214. Due to the smooth profile of the S/D contact holes 311, S/D contacts 214 can be formed with good uniformity and integrity.

At operation 416, the method 400 performs further fabrications to the semiconductor device 200. For example, the method 400 may deposit the dielectric layers 308 and 336 over the ILD layer 306 and the S/D contacts 214 (see FIGS. 2A and 3A), form vias 264 and 242 and butted contacts 269 in the dielectric layers 308 and 336, and form various upper dielectric layers (such as dielectric layers 338, 346, 348, and 356 in FIGS. 2A and 3A) and upper metallic layers (such as metal lines M0 and M1 and vias V0 in FIGS. 2A and 3A).

Although not intended to be limiting, one or more embodiments of the present disclosure provide many benefits to a semiconductor device and the formation thereof. For example, embodiments of the present disclosure provide a process for selectively depositing a capping layer on surfaces of metal gate electrodes and not on surfaces of an ILD layer surrounding the metal gate electrodes. The capping layer protects the metal gate electrodes from oxidation during a process that deposits another ILD layer over the metal gate electrodes. Further, having the capping layer selectively deposited on the metal gate electrodes and not on the ILD layer allows S/D contact holes to be etched with smooth sidewalls, which improves the semiconductor device's reliability. Still further, embodiments of the present disclosure simplify the S/D contact hole etching process because the same material (e.g., silicon oxide) is etched rather than different materials (e.g., both silicon oxide and silicon nitride) are etched.

In one exemplary aspect, the present disclosure is directed to a method for semiconductor fabrication. The method includes forming a metal gate surrounded by a first silicon oxide layer, wherein a metallic surface of the metal gate is exposed; selectively depositing a silicon nitride layer on the metallic surface and not on the first silicon oxide layer; and depositing a second silicon oxide layer on the first silicon oxide layer and on the silicon nitride layer.

In an embodiment of the method, the selectively depositing of the silicon nitride layer includes using an atomic layer deposition (ALD) process that includes a precursor adsorption phase, a first purging phase, a co-reactant adsorption phase, and a second purging phase. In a further embodiment, the precursor adsorption phase is timed such that silicon nitride precursor adsorbs onto the metallic surface and not on the first silicon oxide layer. In a further embodiment, the co-reactant adsorption phase is timed such that silicon nitride co-reactant reacts with the silicon nitride precursor and does not adsorb on the first silicon oxide layer. In a further embodiment, duration for the precursor adsorption phase is in a range from 0.1 second to 3 seconds, and duration for the co-reactant adsorption phase is in a range from 3 seconds to 10 seconds. In a further embodiment, duration for the first purging phase is in a range from 0.5 second to 10 seconds, and duration for the second purging phase is in a range from 0.5 second to 20 seconds.

In an embodiment of the method, the metal gate is sandwiched between two gate spacers and the two gate spacers are surrounded by the first silicon oxide layer, wherein the silicon nitride layer is formed to extend directly on top of the two gate spacers. In another embodiment, the method further includes etching a contact hole adjacent the metal gate, wherein the contact hole extends into the first and the second silicon oxide layers without exposing the silicon nitride layer; and forming a metallic contact in the contact hole. In a further embodiment, a sidewall of the contact hole has a continuously angular face.

In another exemplary aspect, the present disclosure is directed to a method for semiconductor fabrication. The method includes providing a structure having a substrate, a source and a drain over the substrate, one or more semiconductor channel layers connecting the source and the drain, gate spacers over the substrate, a first interlayer dielectric (ILD) layer over the source and the drain and on sidewalls of the gate spacers such that a gate trench is provided between the two gate spacers and exposes the one or more semiconductor channel layers. The method further includes depositing a metal gate electrode into the gate trench and over the gate spacers and the first ILD layer; performing a chemical mechanical planarization process to the metal gate electrode until the first ILD layer is exposed and a top surface of the metal gate electrode is exposed; selectively depositing a silicon nitride layer on the top surface of the metal gate electrode and not on the first ILD layer; and depositing a second ILD layer on the first ILD layer and on the silicon nitride layer.

In an embodiment, the method further includes etching a contact hole adjacent one of the gate spacers and forming a metallic contact in the contact hole, wherein the contact hole extends through the first and the second ILD layers and reaches one of the source and the drain without exposing the silicon nitride layer. In a further embodiment, two opposing sidewalls of the contact hole have continuously angular faces extending through the first and the second ILD layers.

In an embodiment of the method, the selectively depositing of the silicon nitride layer includes using an atomic layer deposition (ALD) process that includes a precursor adsorption phase, a first purging phase, a co-reactant adsorption phase, and a second purging phase, wherein the precursor adsorption phase is controlled such that silicon nitride precursor adsorbs onto the top surface of the metal gate electrode and not on the first ILD layer. In a further embodiment, the co-reactant adsorption phase is controlled such that silicon nitride co-reactant reacts with the silicon nitride precursor and does not adsorb on the first ILD layer. In another further embodiment, duration for the precursor adsorption phase is controlled to be in a range from 0.1 second to 5 seconds. In a further embodiment, duration for the co-reactant adsorption phase is controlled to be in a range from 3 seconds to 10 seconds.

In yet another exemplary aspect, the present disclosure is directed to a semiconductor structure having a metal gate between a source and a drain; a first silicon oxide layer on sidewalls of the metal gate and on top of the source and the drain; a silicon nitride capping layer on top of the metal gate and not on top of the first silicon oxide layer; a second silicon oxide layer on the silicon nitride capping layer and on the first silicon oxide layer; and a first contact in at least the second silicon oxide layer and electrically contacting the source or the drain, wherein the first contact does not directly contact the silicon nitride capping layer.

In an embodiment, the semiconductor structure further includes a gate via penetrating through the second silicon oxide layer and the silicon nitride capping layer and electrically contacting the metal gate. In another embodiment, the semiconductor structure further includes dielectric gate spacers on sidewalls of the metal gate and between the first silicon oxide layer and the metal gate. In a further embodiment, the silicon nitride capping layer has rounded corners directly above the gate spacers.

The foregoing outlines features of several embodiments so that those of ordinary skill in the art may better understand the aspects of the present disclosure. Those of ordinary skill in the art should appreciate that they may readily use the present disclosure as a basis for designing or modifying other processes and structures for carrying out the same purposes and/or achieving the same advantages of the embodiments introduced herein. Those of ordinary skill in the art should also realize that such equivalent constructions do not depart from the spirit and scope of the present disclosure, and that they may make various changes, substitutions, and alterations herein without departing from the spirit and scope of the present disclosure.

What is claimed is:

1. A method for semiconductor fabrication, comprising:
providing a gate structure over a channel region;
depositing gate spacers abutting the gate structure;
forming an oxide layer adjacent the gate structures;
removing the gate structure to form an opening;
forming a metal gate structure in the opening between the gate spacers; and
using an atomic layer deposition (ALD) process to selectively form a silicon nitride layer on an uppermost surface of the metal gate structure, wherein the silicon nitride layer extends to a terminal edge disposed over the gate spacers.

2. The method of claim 1, wherein the ALD process includes a precursor adsorption phase, a first purging phase, a co-reactant adsorption phase, and a second purging phase.

3. The method of claim 1, wherein at least one phase of the ALD process is timed such that a precursor adsorbs onto the uppermost surface of the metal gate structure and not on an exposed upper surface of the oxide layer.

4. The method of claim 1, further comprising:
forming a source/drain region adjacent the channel region.

5. The method of claim 4, further comprising:
forming a contact to the source/drain region, wherein the contact extends through the oxide layer.

6. The method of claim 5, wherein forming the contact includes forming the contact spaced a distance from the silicon nitride layer.

7. The method of claim 1, wherein forming the silicon nitride layer on the uppermost surface of the metal gate structure includes covering an entirety of the uppermost surface of the metal gate structure with the silicon nitride layer.

8. A method for semiconductor fabrication, comprising:
providing a first dielectric layer and a first metal layer forming an uppermost surface having a first region defined by the first metal layer and a second region defined by the first dielectric layer; and
performing an atomic layer deposition (ALD) process in an ALD chamber directed to the uppermost surface, wherein the ALD process includes:
a first step of a precursor adsorption phase including bonding an atom of a precursor and the first region of the uppermost surface to provide a modified first region;
a second step including providing a purging gas flow to remove non-adsorbed atoms of the precursor from the ALD chamber and the second region of the uppermost surface;
a third step of a co-reactant adsorption phase including introducing a co-reactant material and bonding an atom of the co-reactant material with the modified first region; and
a fourth step including providing another purging gas flow to remove non-adsorbed atoms of the co-reactant material from the ALD chamber and the second region of the uppermost surface, wherein the first and third steps are controlled to mitigate bonding with the second region of the uppermost surface.

9. The method of claim 8, wherein the ALD process forms a silicon nitride layer on the first region of the uppermost surface.

10. The method of claim 9, wherein after the ALD process the second region of the uppermost surface is free of the silicon nitride layer.

11. The method of claim 8, wherein the first and third steps are controlled to mitigate bonding with the second region of the uppermost surface by controlling a time period.

12. The method of claim 11, wherein duration for the first step is controlled to be in a range from 0.1 second to 5 seconds.

13. The method of claim 12, wherein the duration for the fourth step is controlled to be in a range from 3 seconds to 10 seconds.

14. The method of claim 8, further comprising: repeating the first step, the second step, the third step and the fourth step.

15. A semiconductor structure, comprising:
a gate structure between a source and a drain and over a channel region;
a gate spacer along sidewalls of the gate structure;
a silicon nitride capping layer on top of the gate structure and the gate spacer, wherein the silicon nitride capping layer has a terminal end approximately vertically aligned with a sidewall of the gate spacer;
an oxide layer on the silicon nitride capping layer and covering the terminal end of the silicon nitride capping layer; and
a first via electrically contacting the gate structure, wherein the first via extends through the oxide layer and the silicon nitride capping layer.

16. The semiconductor structure of claim 15, further comprising:
a contact etch stop layer adjacent the gate spacer.

17. The semiconductor structure of claim 16, wherein the contact etch stop layer interfaces the sidewall of the gate spacer.

18. The semiconductor structure of claim 17, wherein the contact etch stop layer has an upper surface free of the silicon nitride capping layer.

19. The semiconductor structure of claim 18, wherein the upper surface of the contact etch stop layer interfaces the oxide layer.

20. The semiconductor structure of claim 15, wherein the terminal end of the silicon nitride capping layer is rounded.
